(19) United States
(12) Patent Application Publication
(10) Pub. No.: US 2026/0040573 A1
(43) Pub. Date: Feb. 5, 2026

(54) COLUMNAR THREE-DIMENSIONAL MAGNETIC STORAGE UNIT AND WRITING METHOD

(71) Applicant: XI'AN JIAOTONG UNIVERSITY, Xi'an (CN)

(72) Inventors: Tai MIN, Xi'an (CN); Yadong Liu, Xi'an (CN); Xue Zhou, Xi'an (CN)

(21) Appl. No.: 19/205,174

(22) Filed: May 12, 2025

(30) Foreign Application Priority Data
Aug. 1, 2024 (CN) 2024110480013

(51) Int. Cl. H10B 61/00; G11C 11/16; H10N 50/10; H10N 50/85

(52) U.S. Cl. CPC H10B 61/20; G11C 11/161; G11C 11/1675; H10N 50/10; H10N 50/85

(57) ABSTRACT

A columnar three-dimensional magnetic storage unit and a writing method are disclosed. In the magnetic storage unit, a central nanopillar is a nanopillar structure made of a material having a spin-orbit coupling effect; a magnetic storage layer wraps an outer side of the central nanopillar; a magnetic free layer surrounds and contacts the central nanopillar, with a polarization direction of the magnetic free layer extending axially along the nanopillar structure, and the magnetization reversal of the magnetic free layer depending on spin-polarized electrons, whose polarization direction is circumferential, generated by the central nanopillar, a damping-like torque and a field-like torque generated by the spin-polarized electrons synergistically achieving the magnetization precessional reversal of the magnetic free layer; a magnetic tunneling layer wraps an outer side of the magnetic free layer; a magnetic pinned layer wraps an outer side of the magnetic tunneling layer.

### CROSS-REFERENCE TO RELATED APPLICATION

This application claims priority from the Chinese patent application 2024110480013 filed Aug. 1, 2024, the content of which is incorporated herein in the entirety by reference.

### TECHNICAL FIELD

The present disclosure relates to the technical field of memory, and in particular to a columnar three-dimensional magnetic storage unit and a writing method.

### BACKGROUND

The Magnetic Random Access Memory (MRAM) has proven to be one of the most promising universal memories due to its advantages such as non-volatility, high read/write speed, low read/write voltage, and unlimited write cycles. The core storage unit of MRAM is the Magnetic Tunnel Junction (MTJ). MTJ stores data by controlling the relative magnetization directions between two magnetic layers: the pinned layer (PL) and the free layer (FL), which are separated by a spacer layer (SL). The spacer layer can include oxides such as MgO or Al2O3. When the magnetization direction of the FL is parallel to that of the PL, the MTJ exhibits a low resistance state (LRS), also known as the parallel (P) state, corresponding to the binary signal “0”. Conversely, if the magnetization direction of the FL is opposite to that of the PL, the MTJ exhibits a high resistance state (HRS) or the anti-parallel (AP) state, corresponding to the binary signal “1”.

The Spin-Transfer Torque MRAM (STT-MRAM) has become a research hotspot nowadays due to its non-volatility, nearly unlimited read/write cycles, and ultrafast operation speed. However, to achieve a fast read/write speed, the STT-MRAM requires a high current density. As the reversal time shortens to the sub-nanosecond scale, the current density flowing through the MTJ increases exponentially, generating a significant amount of Joule heat. At the same time, the oxide insulating layer of the MTJ may also be broken down by the high current density. The new generation of Spin-Orbit Torque MRAM (SOT-MRAM) addresses these problems. In the SOT-MRAM, the write current does not pass through the oxide insulating layer but is applied to a heavy metal layer or a topological insulator layer beneath the free layer. The current in the heavy metal layer or topological insulator layer is converted into a spin current through spin-orbit coupling and injected into the free layer, driving the reversal of the magnetic torque in the magnetic free layer. Additionally, the SOT-MRAM overcomes the incubation delay present in the STT-MRAM, enabling ultrafast sub-nanosecond reversal. However, the SOT-MRAM introduces new challenges. Compared to the STT-MRAM, each unit in the SOT-MRAM requires three terminals, resulting in a larger area occupied by each unit, which is not conductive to increasing the storage density. Furthermore, the SOT typically only enables the magnetic torque reversal within the XY plane and cannot achieve the out-of-plane perpendicular magnetic torque reversal, which reduces the thermal stability of SOT-MRAM. To achieve perpendicular magnetization reversal, an additional magnetic field is required to assist the reversal, which increases the structural complexity of SOT-MRAM and energy consumption.

Currently, there are several publicly disclosed three-dimensional magnetic devices and writing methods. Three-dimensional magnetic devices can naturally be stacked in the Z-direction, enabling three-dimensional integration of memory chips and exponentially increasing storage density. In micromagnetics, the magnetic ground state refers to the magnetization distribution state that minimizes the energy of the magnetic system. For a magnetic nanoring, its magnetic ground state can typically be classified into the in-plane state, the out-of-plane state (or Z state), and the vortex state. In the in-plane state, the magnetization direction of the magnetic nanoring is uniformly oriented in a direction perpendicular to the ring's axis (within the XY plane). In the Z state, the magnetization direction of the magnetic nanoring is oriented along the ring's axis (±Z, perpendicular to the XY plane). In the vortex state, the magnetization direction of the magnetic nanoring is uniformly arranged in a clockwise or counterclockwise manner along the axial direction of the pillar. Micromagnetic analysis reveals that the magnetic nanoring in the Z state typically occurs at a smaller ring radius compared to the vortex state. Existing designs can only write data to three-dimensional magnetic devices where both the magnetic free layer and the magnetic pinned layer are in the vortex state using SOT currents. Although this approach leverages the high energy efficiency and fast reversal speed of SOT, it still suffers from the drawback of large area occupation in the XY-plane. Therefore, designing a method to achieve reversal of three-dimensional magnetic devices with a Z state as the magnetic ground state using SOT currents is of great significance for further increasing the storage density of three-dimensional magnetic devices, reducing write power consumption, and enhancing write speed.

The information disclosed in the Background section is only for enhancement of understanding of the background of the disclosure and therefore may contain information that does not constitute the prior art that is well known to those of ordinary skill in the art.

### SUMMARY

With respect to the deficiencies or drawbacks of the prior art, a columnar three-dimensional magnetic storage unit and a writing method are provided, the columnar three-dimensional magnetic storage unit occupies a smaller area in the X-Y plane. Data writing is achieved through SOT current pulses, and the precessional reversal of magnetization is utilized for writing operation. This further reduces the write power consumption of the three-dimensional magnetic storage device and enhances its write speed.

The object of the present disclosure is achieved by the following technical solution.

A columnar three-dimensional magnetic storage unit includes,
a central nanopillar, which is a nanopillar structure made of a material having a spin-orbit coupling effect;
a magnetic storage layer, which wraps an outer side of the central nanopillar, the magnetic storage layer including,
a magnetic free layer, which surrounds and contacts the central nanopillar, with a polarization direction of the magnetic free layer extending axially along the nanopillar structure, and the magnetization reversal of the magnetic free layer depending on spin-polarized electrons, whose polarization direction is circumferential, generated by the central nanopillar, a damping-like torque and a field-like torque generated by the spin-polarized electrons synergistically achieving the magnetization precessional reversal of the magnetic free layer,
a magnetic tunneling layer, which wraps an outer side of the magnetic free layer,
a magnetic pinned layer, which wraps an outer side of the magnetic tunneling layer, with a polarization direction of the magnetic pinned layer extending axially along the nanopillar structure;
an outer electrode, which wraps an outer side of the magnetic pinned layer;
a top electrode, which is arranged on an upper side of the central nanopillar; and
a bottom electrode, which is arranged on a lower side of the central nanopillar.

In the columnar three-dimensional magnetic storage unit, when the magnetization direction of the magnetic free layer is parallel to the magnetization direction of the magnetic pinned layer, the three-dimensional magnetic storage unit is in a low resistance state, and when the magnetization direction of the magnetic free layer is anti-parallel to the magnetization direction of the magnetic pinned layer, the three-dimensional magnetic storage unit is in a high resistance state.

In the columnar three-dimensional magnetic storage unit, the magnetization direction of the magnetic pinned layer is fixed to be axially upward or downward along the nanopillar structure, and the magnetization direction of the magnetic free layer is switched between being axially upward or downward along the nanopillar structure.

In the columnar three-dimensional magnetic storage unit, the nanopillar structure is made of a material that converts a current into a spin current, the material including one or more of Nb, Ta, Cr, Mo, W, Re, Ru, Os, Ir, Pd, Pt, Au, Cd, Hg, B, Tl, Sn, Pb, Sb, Bi, Se, Te, Cl, Sm, TaN, WN, Sb₂Te₃, BiSb, Bi₂Se₃, Bi₂Te₃, (BiSb)₂Te₃, HgTe, BiSe, (Bi_{0.57}Sb_{0.43})₂Te₃, TlBiSc₂, Bi_{1.5}Sb_{0.5}Te_{1.8}Se_{1.2}, SnTe, Bi₂₋ₓCrₓSc₃, SmB₆, BiTeCl, and HgTe/CdTe, or one or more of HgTe, BiSb alloy, Bi₂Se₃, Sb₂Te₃, and Bi₂Te₃, wherein x is greater than 0 and less than 2.

In the columnar three-dimensional magnetic storage unit, the magnetic free layer and the magnetic pinned layer are made of ferromagnetic or ferrimagnetic metal and alloys thereof, the ferromagnetic or ferrimagnetic metal and the alloys thereof including one or more of Fe, Co, Ni, Mn, FeCo, FeNi, FePd, FePt, CoPd, CoPt, YCo, LaCo, PrCo, NdCo, SmCo, MnBi, CoFcB, or MnNiSb, and combinations thereof with one or more materials of B, Al, Zr, Hf, Nb, Ta, Cr, Mo, Pd, or Pt; or the magnetic free layer and the magnetic pinned layer are made of a synthetic ferromagnetic or ferrimagnetic material, which includes a multilayer stacked structure of 3d/4d/4f/5d/5f/rare earth metal, such as Co/Ir, Co/Pd, Co/Pt, Co/Au, Co/Ni or CrCo/Pt; or
the magnetic free layer and the magnetic pinned layer are made of a semi-metal ferromagnetic material, which includes a Heusler alloy in the form of XYZ or X2YZ, wherein X includes one or more of Mn, Fe, Co, Ni, Pd, or Cu, Y includes one or more of Ti, V, Cr, Mn, Fc, Co, or Ni, Z includes one or more of Al, Ga, In, Si, Ge, Sn, or Sb; or
the magnetic free layer and the magnetic pinned layer are made of a synthetic antiferromagnetic material, the magnetic free layer and the magnetic pinned layer made of the synthetic antiferromagnetic material are composed of a ferromagnetic layer and a spacer layer, a material of the ferromagnetic layer constituting the magnetic free layer and the magnetic pinned layer includes Fe, Co, Ni, FeCo, CrCoPt or CoFeB, or one or more of materials (Co/Ni) p, (Co/Pd) m or (Co/Pt) n of the ferromagnetic layer in multilayer stacking, wherein m, n, p refers to the number of repetitions in the multilayer stacking; a material constituting the spacer layer includes one or more of Nb, Ta, Cr, Mo, W, Rc, Ru, Os, Rh, Ir, Pt, Cu, Ag, or Au.

In the columnar three-dimensional magnetic storage unit, the magnetic tunneling layer is an oxide, a nitride or an oxynitride, whose constituent elements include one or more of Mg, B, Al, Ca, Sr, La, Ti, Hf, V, Ta, Cr, W, Ru, Cu, In, Si or Eu; or the magnetic tunneling layer is a metal or alloy whose constituent elements include one or more of Mg, Al, Cu, Ag, Au, Y, Ti, V, Nb, Ta, Cr, Mo, W, Ru, Os, Rh, Pd, or Pt; or the magnetic tunneling layer is SiC or a ceramic material.

A writing method of a columnar three-dimensional magnetic storage unit includes the following steps,
applying a read current between the bottom electrode and the outer electrode, and detecting a read voltage between the bottom electrode and the outer electrode, wherein
when the read voltage is less than a threshold voltage, the resistance state of the columnar three-dimensional magnetic storage unit is in a low resistance state; when the read voltage is greater than a threshold voltage, the resistance state of the columnar three-dimensional magnetic storage unit is in a high resistance state, and when the resistance state is in a low resistance state, if first data is to be written, no write current is applied; if second data is to be written, a write current is applied; a write current is applied if first data is to be written when the resistance state is in a high resistance state; if the second data is to be written, no write current is applied.

For the writing method, during writing, a current pulse of 5-1000 ps is applied between a top electrode and a bottom electrode of a central nanopillar with a current density of 0.3-30 MA/cm²; a writing mechanism of a three-dimensional magnetic memory is based on the spin-orbit torque induced precessional magnetization reversal.

For the writing method, a writing process is a unipolar writing manner; the same current polarity realizes switching of the magnetization state of the storage unit from a low resistance state to a high resistance state, and from a high resistance state to a low resistance state.

Compared with the prior art, the beneficial effects brought about by the present disclosure are:
the present disclosure is based on SOT-induced precessional magnetization reversal, which eliminates the need for additional symmetry-breaking methods (such as applying an external magnetic field) during operation, making the process simple. Furthermore, the current pulse length is on the picosecond scale, significantly enhancing the write speed and reducing the write power consumption. The data writing operation module of the present disclosure features a simple structure. Whether to apply a write current depends on the read magnetization state; when the read resistance state is already in the target resistance state to be written, the application of a write current can be avoided, resulting in greater energy efficiency. In the three-dimensional magnetic storage device, the magnetization direction is along the axial direction, which improves the density of the three-dimensional magnetic storage device in the X-Y direction. Specifically, when the radius of the magnetic storage device is large and the height is small, the Heisenberg exchange interaction plays a secondary role, while the magnetostatic energy is dominant. To reduce the magnetostatic energy, the magnetic storage device tends to adopt a vortex state or an in-plane state as its magnetic ground state. Conversely, when the radius of the magnetic storage device is small and the height is large, the Heisenberg exchange interaction is dominant, while the magnetostatic energy plays a secondary role. To minimize the Heisenberg exchange interaction, the magnetic storage device tends to adopt a Z state as its magnetic ground state, namely, the magnetization direction is oriented along the axial direction. Therefore, the magnetization direction of the magnetic storage device being in an out-of-plane state allows for smaller area occupation and increases the array density.

The above description is merely an overview of the technical solutions of the present disclosure, and in order to make the technical means of the present disclosure more clearly understood, to the extent that those skilled in the art can implement it according to the contents of the specification, and to make the above and other objects, features and advantages of the present disclosure more clearly understood, specific embodiments of the present disclosure will be described below with reference to examples.

### BRIEF DESCRIPTION OF DRAWINGS

Various additional advantages and benefits of the present disclosure will become apparent to those of ordinary skill in the art upon reading the following detailed description of the preferred embodiments. The drawings are only for the purpose of illustrating preferred embodiments and are not to be construed as limiting the disclosure. It will be apparent that the drawings described below are merely some embodiments of the present disclosure, and other drawings can be obtained from those of ordinary skill in the art without making creative effort. Also, like reference numerals are used throughout the drawings to designate like parts.

In the drawings:

FIG. 1 is a schematic diagram of three magnetic ground states of a single-domain magnetic nanoring;

FIGS. 2A-2D are distributed phase diagrams between the magnetic ground state of the magnetic nanoring and the magnetic nanoring shape

$$( σ = \frac{D i n}{D o u t} , τ = \frac{H}{D o u t} )$$

for different outer diameters; wherein FIG. 2A is the phase diagram of the magnetic ground state when an outer diameter is 6 nm, FIG. 2B is the phase diagram of the magnetic ground state when an outer diameter is 10 nm, FIG. 2C is the phase diagram of the magnetic ground state when an outer diameter is 20 nm, and FIG. 2D is the phase diagram of the magnetic ground state when an outer diameter is 30 nm;

FIGS. 3A-3B are the structural schematic diagrams of a columnar three-dimensional magnetic storage unit according to the present disclosure; wherein FIG. 3A is a three-dimensional view of the columnar three-dimensional magnetic storage unit, and FIG. 3B is a side cross-sectional view of the columnar three-dimensional magnetic storage unit according to the present disclosure;

FIGS. 4A-4B are schematic diagrams illustrating the current flow direction during the writing process of the columnar three-dimensional magnetic storage unit according to the present disclosure; wherein FIG. 4A is a top view and FIG. 4B is a side cross-sectional view;

FIG. 5A is a diagram illustrating the time evolution trace of the magnetization at one point in the magnetic free layer during the writing process of the columnar three-dimensional magnetic storage unit according to the present disclosure, and FIG. 5B is a diagram illustrating the evolution curve of the magnetization component along the Z-axis direction with time of the magnetization at one point in the magnetic free layer during the writing process of the columnar three-dimensional magnetic storage unit;

FIG. 6 is a schematic diagram illustrating the effects of the current pulse time and current density magnitude on the component of magnetization along the Z-axis at 1 ns (taking the moment when the current is applied as time 0) of the columnar three-dimensional magnetic storage unit according to the present disclosure;

FIGS. 7A-7B are schematic diagrams illustrating the relationship between the direction of the applied current and the transition between the high resistance state and the low resistance state of the columnar three-dimensional magnetic storage unit during the writing process of the columnar three-dimensional magnetic storage unit according to the present disclosure; wherein FIG. 7A illustrates a transition relationship between the high resistance state and the low resistance state corresponding to the application of a series of positive current pulses, and FIG. 7B illustrates a transition relationship between the high resistance state and the low resistance state corresponding to the application of a series of negative current pulses;

FIG. 8 is a flow chart of a writing operation of a data writing operation module of the columnar three-dimensional magnetic storage unit according to the present disclosure;

FIG. 9 is a schematic diagram illustrating the relationship between whether the write current is applied, the data represented by the current resistance, and the target data to be written, as shown in the flow chart of FIG. 8; and

FIG. 10 is a schematic circuit diagram of the data writing operation module of the columnar three-dimensional magnetic storage unit according to the present disclosure.

The present disclosure is further explained below with reference to the accompanying drawings and examples.

### DETAILED DESCRIPTION OF THE INVENTION

Specific embodiments of the disclosure will be described in more detail below with reference to the accompanying drawings. While specific embodiments of the disclosure are illustrated in the accompanying drawings, it should be understood that the disclosure may be embodied in various forms and should not be construed as limited to the embodiments set forth herein. Rather, these embodiments are provided so that the present disclosure will be more fully understood, and will fully convey the scope of the disclosure to those skilled in the art.

It should be noted that certain terms are used throughout the description and claims to refer to certain components. It will be appreciated by those skilled in the art that different terms may be used to refer to the same component. The present description and claims do not refer to differences in nouns as a way of distinguishing components, but use differences in functions of components as a criterion for distinguishing. “Include” or “including” as referred to throughout the description and claims, is an open term that is to be interpreted as “including, but not limited to”. The following description is to describe preferred embodiments for carrying out the disclosure, but the description is for the purpose of the general principles of the description and is not intended to limit the scope of the disclosure. The scope of the disclosure is intended as defined in the appended claims.

In order to facilitate the understanding of the embodiments of the present disclosure, several specific embodiments will be further explained below with reference to the accompanying drawings, and each of the accompanying drawings does not constitute a limitation of the embodiments of the present disclosure.

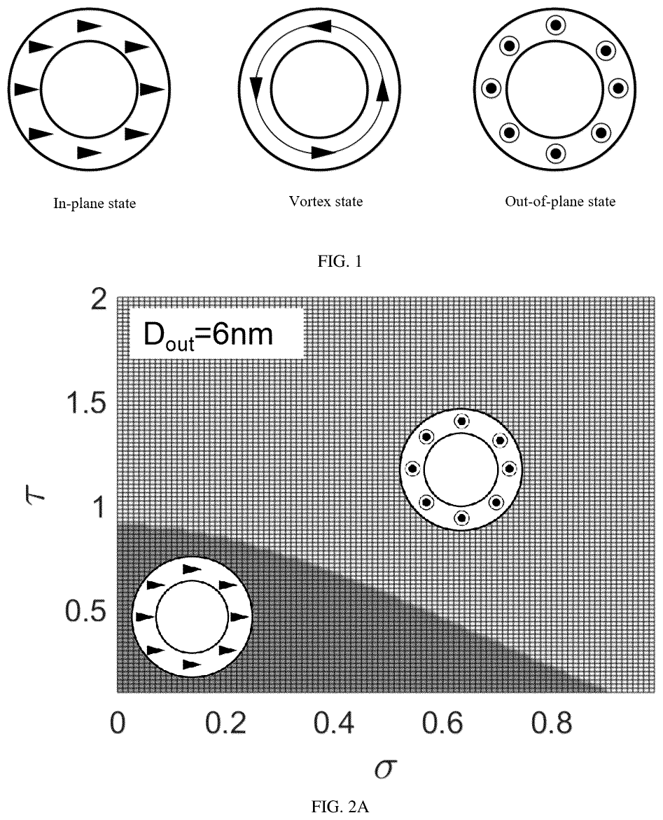

For better understanding, as shown in FIGS. 1 to 10, a columnar three-dimensional magnetic storage unit includes,
a central nanopillar 101, which is a nanopillar structure made of a material having a spin-orbit coupling effect;
a magnetic storage layer, which wraps an outer side of the central nanopillar 101, the magnetic storage layer including,
a magnetic free layer 102, which surrounds and contacts the central nanopillar 101, with a polarization direction of the magnetic free layer 102 extending axially along the nanopillar structure, and the magnetization reversal of the magnetic free layer 102 depending on spin-polarized electrons, whose polarization direction is circumferential, generated by the central nanopillar 101, a damping-like torque and a field-like torque generated by the spin-polarized electrons synergistically achieving the magnetization precessional reversal of the magnetic free layer 102,
a magnetic tunneling layer 103, which wraps an outer side of the magnetic free layer 102,
a magnetic pinned layer 104, which wraps an outer side of the magnetic tunneling layer 103, with a polarization direction of the magnetic pinned layer 104 extending axially along the nanopillar structure;
an outer electrode, which wraps an outer side of the magnetic pinned layer 104;
a top electrode, which is arranged on an upper side of the central nanopillar 101; and
a bottom electrode, which is arranged on a lower side of the central nanopillar 101.

In a preferred embodiment of the columnar three-dimensional magnetic storage unit, when the magnetization direction of the magnetic free layer 102 is parallel to the magnetization direction of the magnetic pinned layer 104, the three-dimensional magnetic storage unit is in a low resistance state, and when the magnetization direction of the magnetic free layer 102 is anti-parallel to the magnetization direction of the magnetic pinned layer 104, the three-dimensional magnetic storage unit is in a high resistance state.

In the preferred embodiment of the columnar three-dimensional magnetic storage unit, the magnetization direction of the magnetic pinned layer 104 is fixed to be axially upward or downward along the nanopillar structure, and the magnetization direction of the magnetic free layer 102 is switched between being axially upward or downward along the nanopillar structure.

In a preferred embodiment of the columnar three-dimensional magnetic storage unit, the unit further includes,
a first electrical terminal 201, which is connected to the top electrode;
a second electrical terminal 202, which is connected to the bottom electrode;
a third electrical terminal 203, which is connected to the outer electrode;
a data writing operation module, which is connected to the first electrical terminal 201, the second electrical terminal 202 and the third electrical terminal to enable data writing via a SOT current pulse.

In a preferred embodiment of the columnar three-dimensional magnetic storage unit, the data writing operation module includes,
a first acquisition module, which is configured to acquire a read voltage of the columnar three-dimensional magnetic storage unit,
a first judgment module, which is connected to the first acquisition module for comparing a relationship of the read voltage and a threshold voltage to judge a resistance value state,
a second judging module, which is connected to the first judging module to judge whether to apply a write current and generate an instruction according to the data to be written and the current resistance state, and
a first control module, which is connected to the second judgment module to perform an operation of whether to apply a write current according to the instruction.

In a preferred embodiment of the columnar three-dimensional magnetic storage unit, the nanopillar structure is made of a material that converts a current into a spin current through a spin Hall effect or a Rashba effect, the material including one or more of Nb, Ta, Cr, Mo, W, Re, Ru, Os, Ir, Pd, Pt, Au, Cd, Hg, B, Tl, Sn, Pb, Sb, Bi, Se, Te, Cl, Sm, TaN, WN, Sb₂Te₃, BiSb, Bi₂Sc₃, Bi₂Te₃, (BiSb)₂Te₃, HgTe, BiSe, (Bi_{0.57}Sb_{0.43})₂Te₃, TlBiSe₂, Bi_{1.5}Sb_{0.5}Te_{1.8}Se_{1.2}, SnTe, Bi₂₋ₓCrₓSe₃, SmB₆, BiTeCl, and HgTe/CdTe, or one or more of HgTe, BiSb alloy, Bi₂Sc₃, Sb₂Te₃, and Bi₂Te₃, wherein x is greater than 0 and less than 2.

In a preferred embodiment of the columnar three-dimensional magnetic storage unit, the magnetic pinned layer 104 is made of ferromagnetic or ferrimagnetic metal and alloys thereof, the ferromagnetic or ferrimagnetic metal and the alloys thereof including one or more of Fe, Co, Ni, Mn, FeCo, FeNi, FePd, FePt, CoPd, CoPt, YCo, LaCo, PrCo, NdCo, SmCo, MnBi, CoFeB, or MnNiSb, and combinations thereof with one or more materials of B, Al, Zr, Hf, Nb, Ta, Cr, Mo, Pd, or Pt; or the magnetic free layer 102 is made of a synthetic ferromagnetic or ferrimagnetic material, which includes a multilayer stacked structure of 3d/4d/4f/5d/5f/rare earth metal, such as Co/Ir, Co/Pd, Co/Pt, Co/Au, Co/Ni or CrCo/Pt.

In a preferred embodiment of the columnar three-dimensional magnetic storage unit, the magnetic free layer 102 is made of a semi-metal ferromagnetic material, which includes a Heusler alloy in the form of XYZ or X2YZ, wherein X includes one or more of Mn, Fe, Co, Ni, Pd, or Cu, Y includes one or more of Ti, V, Cr, Mn, Fe, Co, or Ni, Z includes one or more of Al, Ga, In, Si, Ge, Sn, or Sb; or the magnetic free layer 102 is made of a synthetic antiferromagnetic material, the magnetic free layer 102 made of the synthetic antiferromagnetic material is composed of a ferromagnetic layer and a spacer layer, a material of the ferromagnetic layer constituting the magnetic free layer 102 includes Fe, Co, Ni, FeCo, CrCoPt or CoFeB, or one or more of materials (Co/Ni) p, (Co/Pd) m or (Co/Pt) n of the ferromagnetic layer in multilayer stacking, wherein m, n, p refers to the number of repetitions in the multilayer stacking; a material constituting the spacer layer includes one or more of Nb, Ta, Cr, Mo, W, Re, Ru, Os, Rh, Ir, Pt, Cu, Ag, or Au.

In a preferred embodiment of the columnar three-dimensional magnetic storage unit, the magnetic tunneling layer 103 is an oxide, a nitride or an oxynitride, whose constituent elements include one or more of Mg, B, Al, Ca, Sr, La, Ti, Hf, V, Ta, Cr, W, Ru, Cu, In, Si or Eu; or the magnetic tunneling layer is a metal or alloy whose constituent elements include one or more of Mg, Al, Cu, Ag, Au, Y, Ti, V, Nb, Ta, Cr, Mo, W, Ru, Os, Rh, Pd, or Pt; or the magnetic tunneling layer is SiC or a ceramic material.

A writing method of the columnar three-dimensional magnetic storage unit includes the following steps,
a read current is applied between the bottom electrode and the outer electrode, and a read voltage between the bottom electrode and the outer electrode is detected, wherein
when the read voltage is less than a threshold voltage, the resistance state of the columnar three-dimensional magnetic storage unit is in a low resistance state; when the read voltage is greater than a threshold voltage, the resistance state of the columnar three-dimensional magnetic storage unit is in a high resistance state, and when the resistance state is in a low resistance state, if first data is to be written, no write current is applied; if second data is to be written, a write current is applied; a write current is applied if first data is to be written when the resistance state is in a high resistance state; if the second data is to be written, no write current is applied.

In one embodiment, when the write current is applied to the Z-state columnar three-dimensional magnetic storage unit, it utilizes unipolar writing, meaning that regardless of the current resistance state of the columnar three-dimensional magnetic storage unit, the resistance state will change once the write current is applied. The writing mechanism is based on spin-orbit torque-induced precessional magnetization reversal, which offers a faster write speed and higher energy efficiency. The Z-state columnar three-dimensional magnetic storage unit also occupies a smaller area in the XY plane.

In one embodiment, referring to FIG. 1, FIG. 1 illustrates three magnetic ground states of a magnetic nanoring: the in-plane state, the vortex state, and the out-of-plane state (also referred to as the Z state). For the in-plane state, the magnetization direction of the magnetic nanoring is along the in-plane direction (within the XY plane), and the magnetization direction is the same at every point, with the magnetization direction being any arbitrary direction within the plane. Since the in-plane state is isotropic in terms of its magnetization direction within the plane, it cannot be used for information storage. For the vortex state, the magnetization direction of the magnetic nanoring is also within the in-plane direction (within the XY plane); however, unlike the in-plane state, the magnetization direction of the vortex state rotates clockwise or counterclockwise around the central axis of the ring. For the out-of-plane state, the magnetization direction of the magnetic nanoring is along the out-of-plane direction (perpendicular to the XY plane), and the magnetization direction is consistent at every point, either along the +Z direction or the −Z direction.

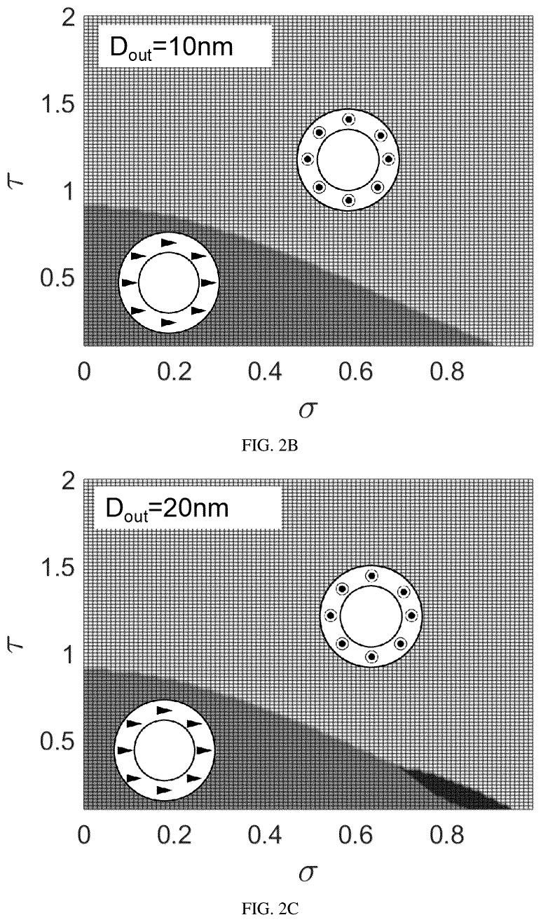

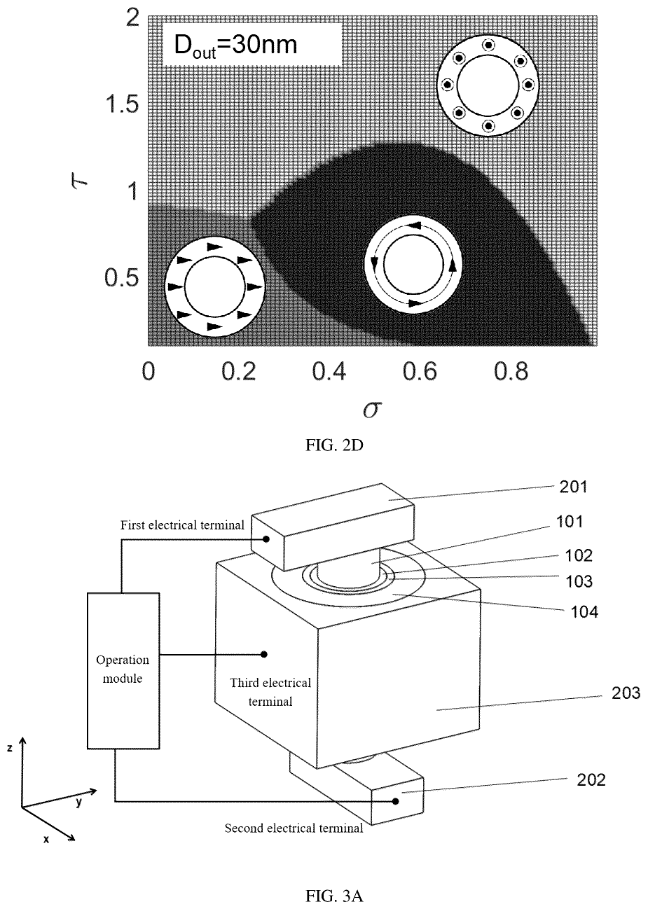

Referring to FIGS. 2A-2D, which take the CoFeB material as an example, the series of phase diagrams describe the relationship between the magnetic ground state and the shape of the magnetic nanoring under different outer diameters. The magnetic ground state of the magnetic nanoring refers to the magnetization state corresponding to the minimum energy of the micromagnetic system. The energy of the micromagnetic system includes shape anisotropy energy, Heisenberg exchange energy, etc. Wherein,

$$σ = \frac{D i n}{D o u t}$$

describes the relative thickness of the magnetic nanoring, with a value greater than 0 and 1.

$$τ = \frac{H}{D o u t}$$

describes the relative height of the magnetic nanoring, with a value greater than 0. FIG. 2A is the phase diagram of the magnetic ground state as a function of inner diameter and height when the outer diameter of the magnetic nanoring is 6 nm. When the inner diameter and height are small, the magnetic ground state tends towards the in-plane state; when the inner diameter and height are larger, the magnetic ground state tends towards the out-of-plane state. In this case, only the in-plane and out-of-plane states are possible. FIG. 2B is the phase diagram of the magnetic ground state as a function of inner diameter and height when the outer diameter of the magnetic nanoring is 10 nm. In this case, the phase diagram is basically consistent with that of FIG. 2A. FIG. 2C is the phase diagram of the magnetic ground state as a function of inner diameter and height when the outer diameter of the magnetic nanoring is 20 nm. It can be seen that when the inner diameter is close to the outer diameter and the height is small, a vortex state region appears in the phase diagram. FIG. 2D is the phase diagram of the magnetic ground state as a function of inner diameter and height when the outer diameter of the magnetic nanoring is 30 nm. At this point, the vortex state region has significantly expanded compared to FIG. 2C. This indicates that the vortex state is more likely to occur when the outer diameter of the magnetic nanoring is larger. Therefore, a three-dimensional magnetic memory with a vortex state as its magnetic ground state is not conducive to shrinkage in the XY direction. Although the in-plane state can occur at a smaller outer diameter, it exhibits in-plane isotropy, making it difficult to serve as the magnetic free layer 102 of the columnar three-dimensional magnetic storage unit. Therefore, the out-of-plane state is the optimal choice for the high-density columnar three-dimensional magnetic storage unit.

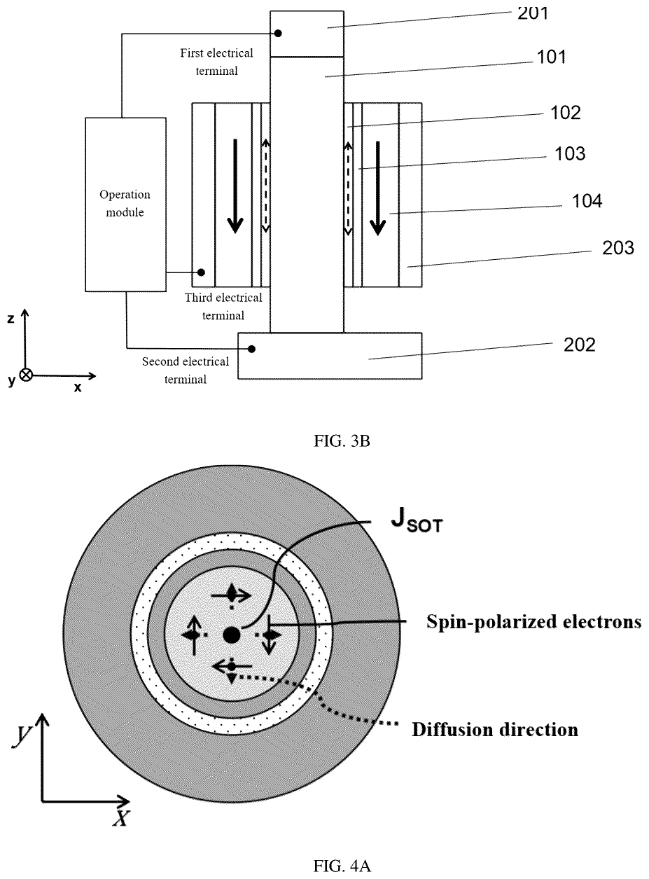

FIGS. 3A-3B are schematic diagrams of the columnar three-dimensional magnetic storage unit according to the present disclosure. For clarity, the structures shown in FIGS. 3A-3B are not drawn to scale. FIG. 3A is a three-dimensional view of the columnar three-dimensional magnetic storage unit, showing the first electrical terminal 201, the second electrical terminal 202, and the third electrical terminal 203. The first electrical terminal 201 and the second electrical terminal 202 are connected by a central nanopillar 101. A magnetic free layer 102 wraps the outer side of the central nanopillar 101, a magnetic tunneling layer 103 wraps an outer side of the magnetic free layer 102, a magnetic pinned layer 104 wraps an outer side of the magnetic tunneling layer 103, the third electrical terminal 203 wraps an outer side of the magnetic pinned layer 104. FIG. 3B is a side cross-sectional view of the columnar three-dimensional magnetic storage unit. The magnetization directions of the magnetic free layer 102 and the magnetic pinned layer 104 are in the z direction. In practical applications, the magnetization direction of the magnetic pinned layer 104 should be fixed, for example, always pointing in the +Z direction or always pointing in the −Z direction. The magnetization direction of the magnetic free layer 102, however, is not fixed. When the magnetization direction of the magnetic free layer 102 is parallel to that of the magnetic pinned layer 104, the three-dimensional magnetic storage unit is in a low-resistance state, and data ‘0’ is stored. When the magnetization direction of the magnetic free layer 102 is antiparallel to that of the magnetic pinned layer 104, the three-dimensional magnetic storage unit is in a high-resistance state, and data ‘1’ is stored.

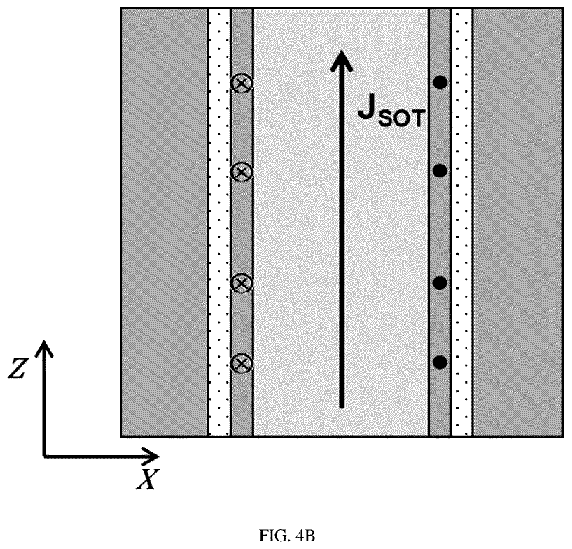

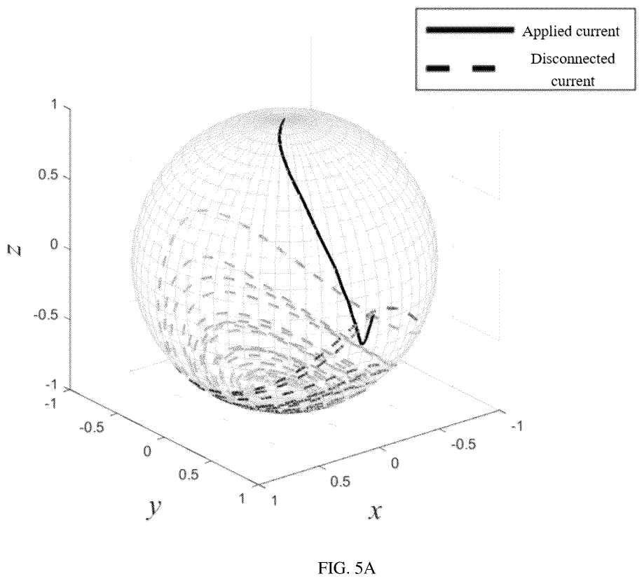

FIGS. 4A-4B are schematic diagrams illustrating the current flow direction during the writing process of the columnar three-dimensional magnetic storage unit according to the present disclosure; wherein FIG. 4A is a top view and FIG. 4B is a side cross-sectional view. When a current JSOT is applied, due to the spin Hall effect, electrons become polarized within the central nanopillar 101, and electrons with different polarization directions diffuse in different directions. As shown in FIG. 4A, according to the spin Hall effect, electrons polarized in the +y direction diffuse in the −x direction, while electrons polarized in the −y direction diffuse in the +x direction. As shown in FIG. 4B, when the spin-polarized electrons diffuse to the magnetic free layer, the resulting spins will rotate around the nanopillar. The spin-polarized electrons exert a damping-like torque and a field-like torque on the magnetic free layer 102. The direction of the damping-like torque is −\vec{m}×(\vec{m}×d), and the direction of the field-like torque is −\vec{m}×\vec{σ}, wherein \vec{m} is the magnetization direction vector at a point in the free layer 102, and \vec{σ} is the spin polarization direction of the electrons acting at that point. These two torques act on the magnetization intensity in two different ways. The damping-like torque always applies a torque that aligns the magnetization vector \vec{m} in the direction of \vec{σ}, while the field-like torque always applies a torque that causes the magnetization vector \vec{m} to precess around \vec{σ}. It should be noted that due to the radial symmetry of the magnetic free layer, points at the same height but different angles should exhibit radially symmetric dynamic behavior. After the current is applied, the magnetization vector \vec{m} precesses around \vec{σ}, and due to the action of the damping-like torque, the precession cone angle gradually decreases. As the precession cone angle decreases, both the field-like torque and the damping-like torque also decrease, leading to a gradual reduction in the precession frequency. When the magnetization vector \vec{m} precesses to the point where the Z-component is less than 0, the SOT current is turned off, and the magnetization vector \vec{m} will relax to the −Z direction under the influence of the effective field, thereby achieving reversal. It should be noted that even if the SOT current is not turned off, due to the influence of the effective field, the SOT and the effective field will eventually reach equilibrium. If the equilibrium point is at a point where the magnetization vector m_{z} is less than 0, turning off the SOT current will cause the magnetization intensity to relax to the −Z direction under the influence of the effective field, and vice versa.

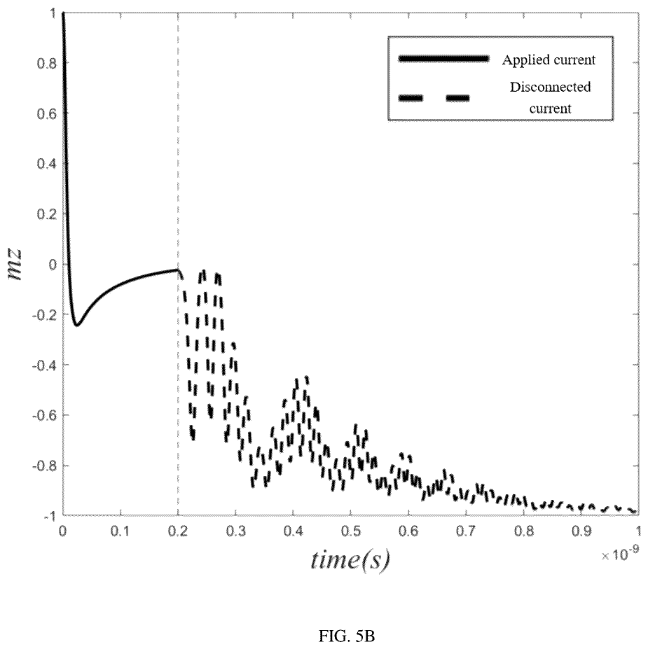

FIG. 5A is a diagram illustrating the time evolution trace of the magnetization at one point during the writing process of the columnar three-dimensional magnetic storage unit according to the present disclosure, and FIG. 5B is a diagram illustrating the evolution curve of the magnetization component along the Z-axis direction with time at one point during the writing process of the columnar three-dimensional magnetic storage unit; at the initial moment, the magnetization direction at this point is along the +z direction, and after a current is applied, the magnetization direction at this point precesses towards the −z direction. When the magnetization component m_{z} becomes less than 0 along the z-axis, the current is disconnected. Due to the effect of magnetic anisotropy, the magnetization will automatically stabilize in the −z direction, achieving deterministic magnetization reversal.

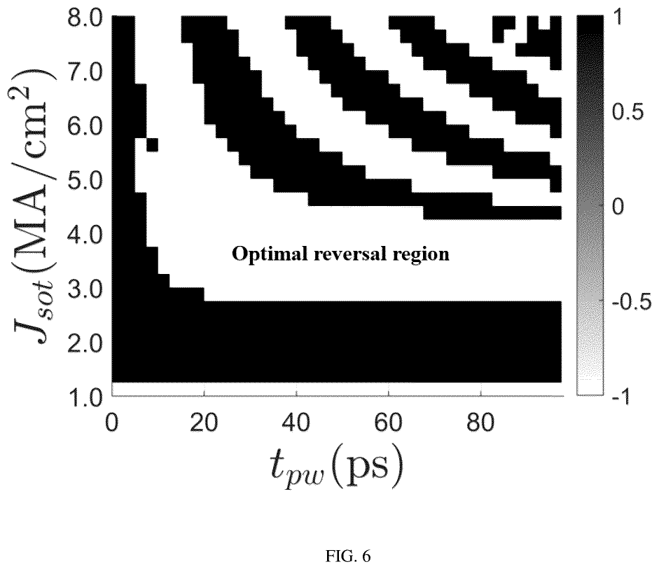

FIG. 6 is a schematic diagram illustrating the effects of the current pulse time and current density magnitude on the component of magnetization along the Z-axis at 1 ns (taking the moment when the current is applied as time 0) of the columnar three-dimensional magnetic storage unit according to the present disclosure. This phase diagram is the simulation result of micromagnetic simulations, wherein a CoFeB material is used as the magnetic free layer. The inner radius of the free layer is 4 nm, the outer radius is 5 nm, and the height is 20 nm. In the initial state, the magnetization direction of the magnetic free layer is along the +z direction. The horizontal axis represents the applied current pulse time, and the vertical axis represents the magnitude of the applied current density. The color of the graph represents the magnetization direction of the magnetic free layer after the current is applied. Black represents a magnetization direction along the +z direction, indicating no magnetization reversal; white represents a magnetization direction along the −z direction, indicating magnetization reversal has occurred. When the current density is less than 2.8 MA/cm², the magnetic free layer 102 does not undergo magnetization reversal for any current pulse time. When the current density is greater than 2.8 MA/cm² and less than 4.5 MA/cm², the magnetization of the magnetic free layer 102 will reverse as long as the current pulse time exceeds a certain threshold. When the current density is greater than 4.5 MA/cm², the magnetization of the magnetic free layer 102 oscillates between reversed and non-reversed states as the current pulse time increases. Therefore, for the columnar three-dimensional magnetic storage unit, to achieve successful writing, the applied current pulse time and current density magnitude should be within the white region of the phase diagram shown in FIG. 6. To achieve faster writing and lower power consumption, the applied current pulse time and current density magnitude should be within the optimal reversal region of the phase diagram shown in FIG. 6.

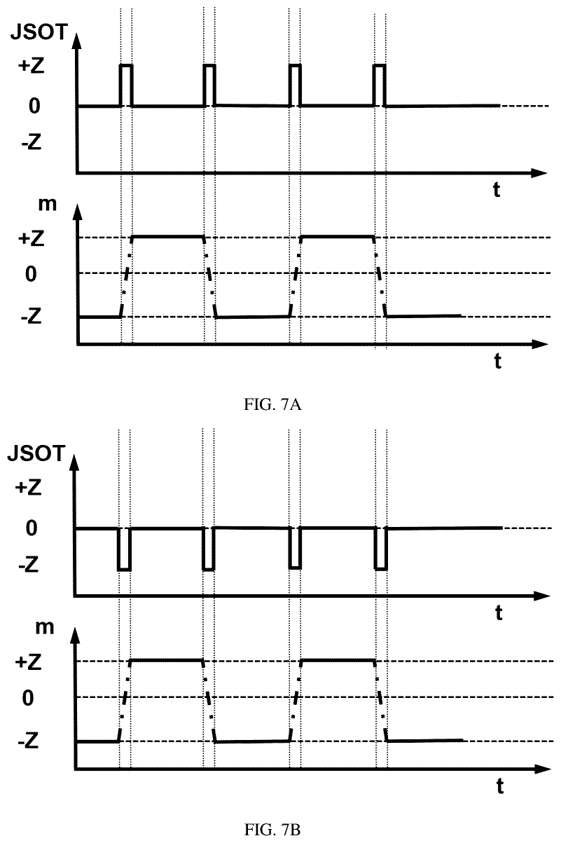

FIGS. 7A-7B are schematic diagrams illustrating the relationship between the direction of the applied current and the transition between the high resistance state and the low resistance state of the columnar three-dimensional magnetic storage unit during the writing process of the columnar three-dimensional magnetic storage unit according to the present disclosure.

Wherein FIG. 7A illustrates a transition relationship between the high resistance state and the low resistance state corresponding to the application of a series of positive current pulse. The pulse length and current density of the applied positive current pulse referred to here should be within the white regions shown in FIGS. 5A and 5B. Initially, the columnar three-dimensional magnetic storage unit is in the low resistance state. After applying a positive current pulse once, the columnar three-dimensional magnetic storage unit transitions from the low resistance state to the high resistance state. Upon applying a second positive current pulse, the columnar three-dimensional magnetic storage unit transitions from the high resistance state to the low resistance state. For the subsequent two positive current pulses, each one causes the resistance state of the columnar three-dimensional magnetic storage unit to switch once.

FIG. 7B illustrates a transition relationship between the high resistance state and the low resistance state corresponding to the application of a series of negative current pulses. Similar to the positive current pulse, each negative current pulse also induces a resistance state transition. Therefore, regardless of the direction of the current pulse, as long as the current pulse length and current density magnitude meet the reversal requirements indicated by the white regions in FIGS. 5A and 5B, the resistance state of the columnar three-dimensional magnetic storage unit will undergo reversal. This strategy is referred to as a unipolar writing strategy.

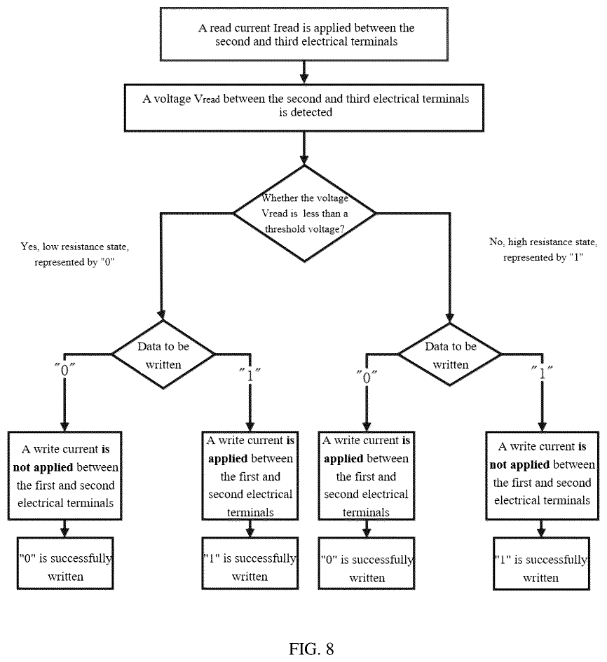

FIG. 8 is a flow chart of a writing operation of a data writing operation module of the columnar three-dimensional magnetic storage unit according to the present disclosure. As shown in FIGS. 7A-7B, the writing strategy for the Z-state three-dimensional magnetic storage unit is unipolar writing. Therefore, it is necessary to know the current resistance state before confirming the write operation. To do this, a read current Iread is first applied between the second and third electrical terminals to obtain a read voltage Vread between the two electrical terminals. This read voltage is then compared to a reference voltage Vref. If the read voltage Vread is less than the reference voltage Vref, it indicates that the three-dimensional magnetic storage unit is currently in the low resistance state, and data ‘0’ is stored. If the read voltage Vread is greater than the reference voltage Vref, it indicates that the three-dimensional magnetic storage unit is currently in the high resistance state, and data ‘1’ is stored. Next, if the current stored data is ‘0’, and if data ‘0’ is to be written, no write current is needed, and the final data remains ‘0’. If data ‘1’ is to be written, a write current is needed to be applied, and the final data becomes ‘1’. If the current stored data is ‘1’, and if data ‘0’ is to be written, a write current is needed to be applied, and the final data becomes ‘0’. If data ‘1’ is to be written, no write current is needed to be applied, and the final data remains ‘1’.

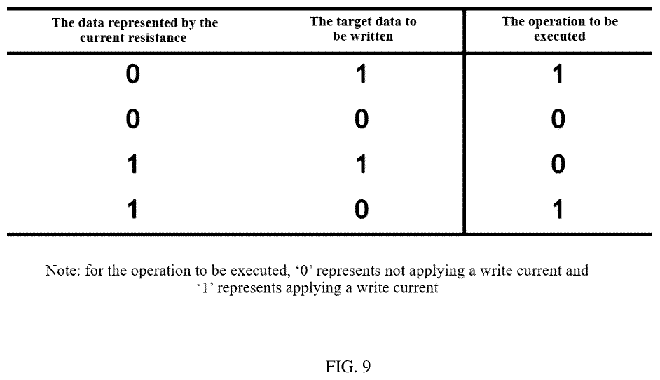

For the operation to be executed, if logical ‘0’ represents not applying a write current and logical ‘1’ represents applying a write current, then the relationship between whether the write current is applied, the data represented by the current resistance, and the target data to be written is an XOR relationship, as shown in FIG. 9. A write current is applied if and only if one of the data represented by the current resistance and the target data to be written is ‘1’.

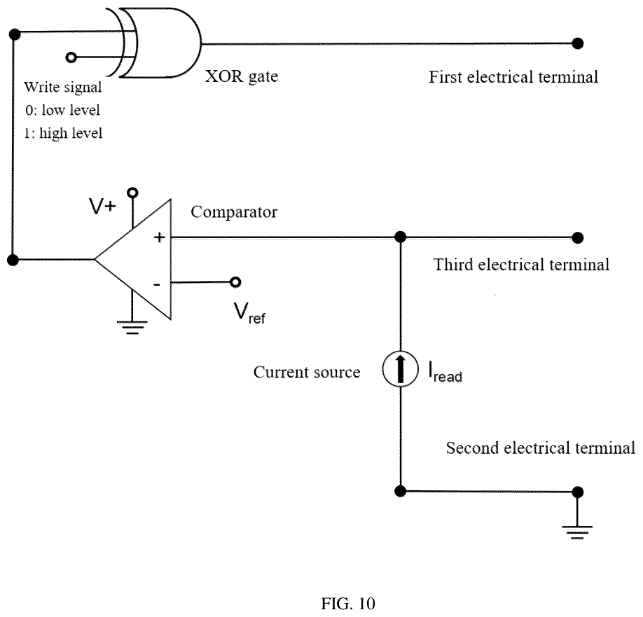

FIG. 10 is a schematic circuit diagram of the data writing operation module of the Z-state three-dimensional magnetic storage unit according to the present disclosure. First, a current source is used to apply a read current between the second and third electrical terminals. Since the second electrical terminal is grounded, the voltage at the third electrical terminal is a read voltage Vread. This read voltage Vread is then passed through a comparator to compare it with a reference voltage Vref. If the read voltage Vread is greater than the reference voltage Vref, a high level is output; otherwise, a low level is output. Next, an output signal from the comparator undergoes an XOR operation with the write signal. If the XOR gate outputs a high level, a write voltage is applied to the first electrical terminal, causing the magnetization reversal of the free layer. If the XOR gate outputs a low level, no write voltage is applied to the first electrical terminal, and there is no magnetization reversal of the free layer.

The basic principles of the present application have been described above in connection with specific embodiments, however, it should be noted that the advantages, effects and the like mentioned in the present application are only examples and not limitations, and these advantages, effects and the like are not to be considered as essential requirements in the various embodiments of the present application. In addition, the foregoing disclosure of specific details has been presented for purposes of illustration and understanding only, and is not intended to limit the disclosure to the extent that it must be practiced with specific details.

The foregoing description has been presented for purposes of illustration and description. Furthermore, this description is not intended to limit embodiments of the present application to the form disclosed herein. While a number of example aspects and embodiments have been discussed above, those of skill in the art will recognize certain variations, modifications, changes, additions and sub-combinations thereof.

1. A columnar three-dimensional magnetic storage unit, comprising,
a central nanopillar, which is a nanopillar structure made of a material having a spin-orbit coupling effect;
a magnetic storage layer, which wraps an outer side of the central nanopillar, the magnetic storage layer comprising,
a magnetic free layer, which surrounds and contacts the central nanopillar, with a polarization direction of the magnetic free layer extending axially along the nanopillar structure, and the magnetization reversal of the magnetic free layer depending on spin-polarized electrons, whose polarization direction is circumferential, generated by the central nanopillar, a damping-like torque and a field-like torque generated by the spin-polarized electrons synergistically achieving the magnetization precessional reversal of the magnetic free layer,
a magnetic tunneling layer, which wraps an outer side of the magnetic free layer,
a magnetic pinned layer, which wraps an outer side of the magnetic tunneling layer, with a polarization direction of the magnetic pinned layer extending axially along the nanopillar structure;
an outer electrode, which wraps an outer side of the magnetic pinned layer;
a top electrode, which is arranged on an upper side of the central nanopillar; and
a bottom electrode, which is arranged on a lower side of the central nanopillar.

2. The columnar three-dimensional magnetic storage unit according to claim 1, wherein, preferably, when the magnetization direction of the magnetic free layer is parallel to the magnetization direction of the magnetic pinned layer, the three-dimensional magnetic storage unit is in a low resistance state, and when the magnetization direction of the magnetic free layer is anti-parallel to the magnetization direction of the magnetic pinned layer, the three-dimensional magnetic storage unit is in a high resistance state.

3. The columnar three-dimensional magnetic storage unit according to claim 1, wherein the magnetization direction of the magnetic pinned layer is fixed to be axially upward or downward along the nanopillar structure, and the magnetization direction of the magnetic free layer is switched between being axially upward or downward along the nanopillar structure.

4. The columnar three-dimensional magnetic storage unit according to claim 1, wherein the nanopillar structure is made of a material that converts a current into a spin current, the material comprising one or more of Nb, Ta, Cr, Mo, W, Re, Ru, Os, Ir, Pd, Pt, Au, Cd, Hg, B, Tl, Sn, Pb, Sb, Bi, Se, Te, Cl, Sm, TaN, WN, Sb₂Te₃, BiSb, Bi₂Sc₃, Bi₂Te₃, (BiSb)₂Te₃, HgTe, BiSe, (Bi_{0.57}Sb_{0.43})₂Te₃, TlBiSe₂, Bi_{1.5}Sb_{0.5}Te_{1.8}Se_{1.2}, SnTe, Bi₂₋ₓCrₓSc₃, SmB₆, BiTeCl, and HgTe/CdTe, or one or more of HgTe, BiSb alloy, Bi₂Se₃, Sb₂Te₃, and Bi₂Te₃, wherein x is greater than 0 and less than 2.

5. The columnar three-dimensional magnetic storage unit according to claim 1, wherein the magnetic free layer and the magnetic pinned layer are made of ferromagnetic or ferrimagnetic metal and alloys thereof, the ferromagnetic or ferrimagnetic metal and the alloys thereof comprising one or more of Fe, Co, Ni, Mn, FeCo, FeNi, FePd, FePt, CoPd, CoPt, YCo, LaCo, PrCo, NdCo, SmCo, MnBi, CoFcB, or MnNiSb, and combinations thereof with one or more materials of B, Al, Zr, Hf, Nb, Ta, Cr, Mo, Pd, or Pt; or the magnetic free layer and the magnetic pinned layer are made of a synthetic ferromagnetic or ferrimagnetic material, which comprises a multilayer stacked structure of 3d/4d/4f/5d/5f/rare earth metal, such as Co/Ir, Co/Pd, Co/Pt, Co/Au, Co/Ni or CrCo/Pt; or
the magnetic free layer and the magnetic pinned layer are made of a semi-metal ferromagnetic material, which comprises a Heusler alloy in the form of XYZ or X2YZ, wherein X comprises one or more of Mn, Fe, Co, Ni, Pd, or Cu, Y comprises one or more of Ti, V, Cr, Mn, Fe, Co, or Ni, Z comprises one or more of Al, Ga, In, Si, Ge, Sn, or Sb; or
the magnetic free layer and the magnetic pinned layer are made of a synthetic antiferromagnetic material, the magnetic free layer and the magnetic pinned layer made of the synthetic antiferromagnetic material are composed of a ferromagnetic layer and a spacer layer, a material of the ferromagnetic layer constituting the magnetic free layer and the magnetic pinned layer comprises Fe, Co, Ni, FeCo, CrCoPt or CoFeB, or one or more of materials (Co/Ni) p, (Co/Pd) m or (Co/Pt) n of the ferromagnetic layer in multilayer stacking, wherein m, n, p refers to the number of repetitions in the multilayer stacking; a material constituting the spacer layer comprises one or more of Nb, Ta, Cr, Mo, W, Re, Ru, Os, Rh, Ir, Pt, Cu, Ag, or Au.

6. The columnar three-dimensional magnetic storage unit according to claim 1, wherein the magnetic tunneling layer is an oxide, a nitride or an oxynitride, whose constituent elements comprise one or more of Mg, B, Al, Ca, Sr, La, Ti, Hf, V, Ta, Cr, W, Ru, Cu, In, Si or Eu; or the magnetic tunneling layer is a metal or alloy whose constituent elements comprise one or more of Mg, Al, Cu, Ag, Au, Y, Ti, V, Nb, Ta, Cr, Mo, W, Ru, Os, Rh, Pd, or Pt; or the magnetic tunneling layer is SiC or a ceramic material.

7. A writing method of a columnar three-dimensional magnetic storage unit, wherein the method uses the columnar three-dimensional magnetic storage unit according to claim 1.

8. The writing method according to claim 7, wherein, during writing, a current pulse of 5-1000 ps is applied between a top electrode and a bottom electrode of a central nanopillar with a current density of 0.3-30 MA/cm²; a writing mechanism of the three-dimensional magnetic storage unit is based on the spin-orbit torque induced precessional magnetization reversal.

9. The writing method according to claim 7, wherein a writing process is a unipolar writing manner; the same current polarity realizes switching of the magnetization state of the storage unit from a low resistance state to a high resistance state, and from a high resistance state to a low resistance state.

10. The writing method of claim 7, wherein, preferably, when the magnetization direction of the magnetic free layer is parallel to the magnetization direction of the magnetic pinned layer, the three-dimensional magnetic storage unit is in a low resistance state, and when the magnetization direction of the magnetic free layer is anti-parallel to the magnetization direction of the magnetic pinned layer, the three-dimensional magnetic storage unit is in a high resistance state.

11. The writing method of claim 7, wherein the magnetization direction of the magnetic pinned layer is fixed to be axially upward or downward along the nanopillar structure, and the magnetization direction of the magnetic free layer is switched between being axially upward or downward along the nanopillar structure.

12. The writing method of claim 7, wherein the nanopillar structure is made of a material that converts a current into a spin current, the material comprising one or more of Nb, Ta, Cr, Mo, W, Re, Ru, Os, Ir, Pd, Pt, Au, Cd, Hg, B, Tl, Sn, Pb, Sb, Bi, Se, Te, Cl, Sm, TaN, WN, Sb₂Te₃, BiSb, Bi₂Se₃, Bi₂Te₃, (BiSb)₂Te₃, HgTe, BiSe, (Bi_{0.57}Sb_{0.43})₂Te₃, TlBiSe₂, Bi_{1.5}Sb_{0.5}Te_{1.8}Se_{1.2}, SnTe, Bi₂₋ₓCrₓSe₃, SmB₆, BiTeCl, and HgTe/CdTe, or one or more of HgTe, BiSb alloy, Bi₂Se₃, Sb₂Te₃, and Bi₂Te₃, wherein x is greater than 0 and less than 2.

13. The writing method of claim 7, wherein the magnetic free layer and the magnetic pinned layer are made of ferromagnetic or ferrimagnetic metal and alloys thereof, the ferromagnetic or ferrimagnetic metal and the alloys thereof comprising one or more of Fe, Co, Ni, Mn, FeCo, FeNi, FePd, FePt, CoPd, CoPt, YCo, LaCo, PrCo, NdCo, SmCo, MnBi, CoFeB, or MnNiSb, and combinations thereof with one or more materials of B, Al, Zr, Hf, Nb, Ta, Cr, Mo, Pd, or Pt; or the magnetic free layer and the magnetic pinned layer are made of a synthetic ferromagnetic or ferrimagnetic material, which comprises a multilayer stacked structure of 3d/4d/4f/5d/5f/rare earth metal, such as Co/Ir, Co/Pd, Co/Pt, Co/Au, Co/Ni or CrCo/Pt; or
the magnetic free layer and the magnetic pinned layer are made of a semi-metal ferromagnetic material, which comprises a Heusler alloy in the form of XYZ or X2YZ, wherein X comprises one or more of Mn, Fe, Co, Ni, Pd, or Cu, Y comprises one or more of Ti, V, Cr, Mn, Fe, Co, or Ni, Z comprises one or more of Al, Ga, In, Si, Ge, Sn, or Sb; or
the magnetic free layer and the magnetic pinned layer are made of a synthetic antiferromagnetic material, the magnetic free layer and the magnetic pinned layer made of the synthetic antiferromagnetic material are composed of a ferromagnetic layer and a spacer layer, a material of the ferromagnetic layer constituting the magnetic free layer and the magnetic pinned layer comprises Fe, Co, Ni, FeCo, CrCoPt or CoFeB, or one or more of materials (Co/Ni) p, (Co/Pd) m or (Co/Pt) n of the ferromagnetic layer in multilayer stacking, wherein m, n, p refers to the number of repetitions in the multilayer stacking; a material constituting the spacer layer comprises one or more of Nb, Ta, Cr, Mo, W, Re, Ru, Os, Rh, Ir, Pt, Cu, Ag, or Au.

14. The writing method of claim 7, wherein the magnetic tunneling layer is an oxide, a nitride or an oxynitride, whose constituent elements comprise one or more of Mg, B, Al, Ca, Sr, La, Ti, Hf, V, Ta, Cr, W, Ru, Cu, In, Si or Eu; or the magnetic tunneling layer is a metal or alloy whose constituent elements comprise one or more of Mg, Al, Cu, Ag, Au, Y, Ti, V, Nb, Ta, Cr, Mo, W, Ru, Os, Rh, Pd, or Pt; or the magnetic tunneling layer is SiC or a ceramic material.
